(19) United States
(12) Patent Application Publication
(10) Pub. No.: US 2025/0210576 A1
(43) Pub. Date: Jun. 26, 2025

(54) SEMICONDUCTOR PACKAGE

(71) Applicant: SAMSUNG ELECTRONICS CO., LTD., Suwon-si (KR)

(72) Inventor: Youngbae KIM, Suwon-si (KR)

(21) Appl. No.: 18/972,030

(22) Filed: Dec. 6, 2024

(30) Foreign Application Priority Data
Dec. 26, 2023 (KR) 10-2023-0191394

(51) Int. Cl. H01L 23/00; H01L 25/18; H10B 80/00

(52) U.S. Cl. CPC H01L 24/32; H01L 24/16; H01L 24/73; H01L 24/83; H01L 24/92; H01L 25/18; H01L 25/50; H01L 2224/16148; H01L 2224/32145; H01L 2224/73104; H01L 2224/81203; H01L 2224/81815; H01L 2224/81986; H01L 2224/83203; H01L 2224/9211; H01L 2224/92242; H01L 2225/06513; H01L 2225/06548; H01L 2225/06555; H10B 80/00

(57) ABSTRACT

A semiconductor package includes first, second and third semiconductor chip stack structures and a molding member. The first semiconductor chip stack structure includes first and second semiconductor chips having first and second planar areas and a first adhesion layer therebetween. The second semiconductor chip stack structure is on and bonded with the first semiconductor chip stack structure, and includes third and fourth semiconductor chips having a third planar area and the second planar area and a second adhesion layer therebetween. The third semiconductor chip stack structure is on the second semiconductor chip stack structure, and includes fifth and sixth semiconductor chips having the third planar area and the second planar area, and a third adhesion layer therebetween. The molding member is on the first semiconductor chip, and covers sidewalls of the first adhesion layer, the second semiconductor chip, and the second and third semiconductor chip stack structures.

### CROSS-REFERENCE TO RELATED APPLICATION

This application claims priority under 35 U.S.C. § 119 to Korean Patent Application No. 10-2023-0191394, filed on Dec. 26, 2023 in the Korean Intellectual Property Office (KIPO), the contents of which are herein incorporated by reference in their entirety.

### FIELD

Example embodiments relate to a semiconductor package. More particularly, example embodiments relate to a multi-chip package including a plurality of stacked chips.

### BACKGROUND

A high bandwidth memory (HBM) package may include a plurality of memory chips stacked in a vertical direction on a logic chip, and the memory chips may be bonded with each other through an adhesion layer. If the bonding state between the memory chips is good, the HBM package may have a good performance, and thus a study for enhancing the bonding state between the memory chips is needed.

### SUMMARY

Example embodiments provide a semiconductor package having enhanced electrical characteristics.

According to example embodiments, there is provided a semiconductor package. The semiconductor package may include first, second and third semiconductor chip stack structures and a molding member. The first semiconductor chip stack structure may include a first semiconductor chip having a first planar area, a second semiconductor chip on the first semiconductor chip and having a second planar area smaller than the first planar area, and a first adhesion layer between the first and second semiconductor chips and bonding the first and second semiconductor chips to each other. The second semiconductor chip stack structure may be on and bonded with the first semiconductor chip stack structure. The second semiconductor chip stack structure may include a third semiconductor chip having a third planar area smaller than the first planar area and greater than the second planar area, a fourth semiconductor chip on the third semiconductor chip and having the second planar area, and a second adhesion layer between the third and fourth semiconductor chips and bonding the third and fourth semiconductor chips to each other. The third semiconductor chip stack structure may be on the second semiconductor chip stack structure. The third semiconductor chip stack structure may include a fifth semiconductor chip having the third planar area, a sixth semiconductor chip on the fifth semiconductor chip and having the second planar area, and a third adhesion layer between the fifth and sixth semiconductor chips and bonding the fifth and sixth semiconductor chips to each other. The molding member may be on the first semiconductor chip, and may cover sidewalls of the first adhesion layer, the second semiconductor chip, and the second and third semiconductor chip stack structures.

According to example embodiments, there is provided a semiconductor package. The semiconductor package may include first, second and third semiconductor chip stack structures, and a molding member. The first semiconductor chip stack structure may include a first semiconductor chip, a second semiconductor chip on the first semiconductor chip, and a first bonding layer structure between the first and second semiconductor chips, bonding the first and second semiconductor chips to each other, and surrounding a first bonding pattern structure that contacts the first and second semiconductor chips. The second semiconductor chip stack structure may include a third semiconductor chip, a fourth semiconductor chip on the third semiconductor chip, and a second bonding layer structure between the third and fourth semiconductor chips, bonding the third and fourth semiconductor chips to each other, and surrounding a second bonding pattern structure that contacts the third and fourth semiconductor chips. The third semiconductor chip stack structure may include a fifth semiconductor chip, a sixth semiconductor chip on the fifth semiconductor chip, and a third bonding layer structure between the fifth and sixth semiconductor chips, bonding the fifth and sixth semiconductor chips to each other, and surrounding a third bonding pattern structure that contacts the fifth and sixth semiconductor chips. The molding member may be on the first semiconductor chip, and may surround sidewalls of the first bonding layer structure, the second semiconductor chip, and the second and third semiconductor chip stack structures. The first and second semiconductor chip stack structures may be bonded to each other with a first conductive bump therebetween. The second and third semiconductor chip stack structures may be bonded to each other with a second conductive bump therebetween. The molding member may contact and surround side surfaces of the first and second conductive bumps.

According to example embodiments, there is provided a semiconductor package. The semiconductor package may include first, second and third chip stack structures, fourth and fifth conductive connection members, and a molding member. The first semiconductor chip stack structure may include a first semiconductor chip having a first planar area, a second semiconductor chip on the first semiconductor chip and having a second planar area smaller than the first planar area, a first conductive connection member between the first and second semiconductor chips and electrically connecting the first and second semiconductor chips to each other, and a first adhesion layer between the first and second semiconductor chips, bonding the first and second semiconductor chips to each other and covering a sidewall of the first conductive connection member. The second semiconductor chip stack structure may be on the first semiconductor chip stack structure. The second semiconductor chip stack structure may include a third semiconductor chip having a third planar area smaller than the first planar area and greater than the second planar area, a fourth semiconductor chip on the third semiconductor chip and having the second planar area, a second conductive connection member between the third and fourth semiconductor chips and electrically connecting the third and fourth semiconductor chips to each other, and a second adhesion layer between the third and fourth semiconductor chips, bonding the third and fourth semiconductor chips to each other and covering a sidewall of the second conductive connection member. The third semiconductor chip stack structure may be on the second semiconductor chip stack structure. The third semiconductor chip stack structure may include a fifth semiconductor chip having the third planar area, a sixth semiconductor chip on the fifth semiconductor chip and having the second planar area, a third conductive connection member between the fifth and sixth semiconductor chips and electrically connecting the fifth and sixth semiconductor chips to each other, and a third adhesion layer between the fifth and sixth semiconductor chips, bonding the fifth and sixth semiconductor chips to each other and covering a sidewall of the third conductive connection member. The fourth conductive connection member may be between the first and second semiconductor chip stack structures, and may electrically connect the first and second semiconductor chip stack structures to each other. The fifth conductive connection member may be between the second and third semiconductor chip stack structures, and may electrically connect the second and third semiconductor chip stack structures to each other. The molding member may be on the first semiconductor chip, and may cover sidewalls of the first adhesion layer, the second semiconductor chip, the second and third semiconductor chip stack structures, and the fourth and fifth conductive connection members.

When the semiconductor package in accordance with example embodiments is manufactured, warpage of the semiconductor chips may be prevented so that the conductive connection members between the semiconductor chips may be well bonded with the conductive pads in the semiconductor chips. Accordingly, the electrical connections between the semiconductor chips may be improved so that the semiconductor package may have enhanced electrical characteristics.

### BRIEF DESCRIPTION OF THE DRAWINGS

FIG. 1 is a cross-sectional view illustrating a semiconductor package in accordance with example embodiments.

FIGS. 2 to 11 are cross-sectional views illustrating a method of manufacturing a semiconductor package in accordance with example embodiments.

FIGS. 12 and 13 are cross-sectional views illustrating semiconductor packages in accordance with example embodiments.

FIG. 14 is a cross-sectional view illustrating a semiconductor package in accordance with example embodiments.

FIG. 15 is a cross-sectional view illustrating an electronic device in accordance with example embodiments.

### DETAILED DESCRIPTION

Hereinafter, example embodiments will be explained in detail with reference to the accompanying drawings. Hereinafter, a direction substantially parallel to an upper surface of a wafer or a substrate may be referred to as a horizontal direction, and a direction substantially perpendicular to the upper surface of the wafer or the substrate may be referred to as a vertical direction.

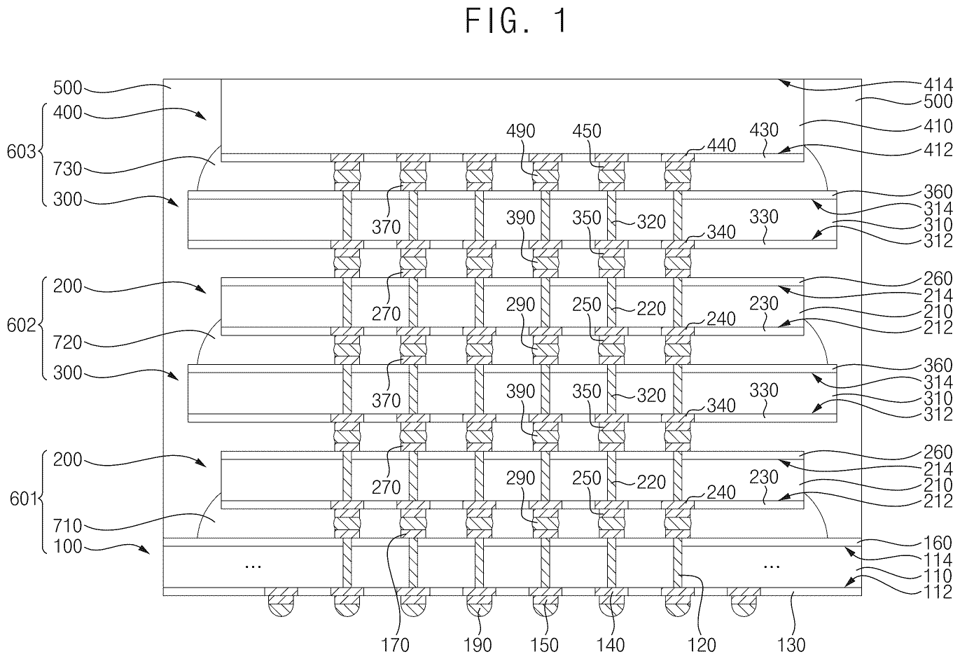

FIG. 1 is a cross-sectional view illustrating a semiconductor package in accordance with example embodiments.

Referring to FIG. 1, the semiconductor package may include first, second, and third semiconductor chip stack structures 601, 602 and 603 and a molding member 500.

FIG. 1 shows that the semiconductor package includes a single second semiconductor chip stack structure between the first and third semiconductor chip stack structures 601 and 603, however, the inventive concept may not be limited thereto, and a plurality of second semiconductor chip stack structures may be disposed between the first and third semiconductor chip stack structures 601 and 603.

In example embodiments, the semiconductor package may be a high bandwidth memory (HBM) package.

The first semiconductor chip stack structure 601 may include a first semiconductor chip 100, a second semiconductor chip 200 and a first adhesion layer 710 between the first and second chips 100 and 200, the second semiconductor chip stack structure 602 may include a third semiconductor chip 300, the semiconductor chip 200 and a second adhesion layer 720 between the third and second chips 300 and 200, and the third semiconductor chip stack structure 603 may include the third semiconductor chip 300, a fourth semiconductor chip 400 and a third adhesion layer 730 between the third and fourth chips 300 and 400.

In example embodiments, the first semiconductor chip 100 may be a buffer die, and may include a logic device, e.g., a controller. Each of the second to fourth semiconductor chips 200, 300 and 400 may be a core die, and may include a volatile memory device, e.g., DRAM device, SRAM device, etc., or a non-volatile memory device, e.g., flash memory device, EEPROM device, etc.

Thus, the first semiconductor chip 100 may also referred to as a logic die or a logic chip, and each of the second to fourth semiconductor chips 200, 300 and 400 may be referred to as a memory die or a memory chip. Additionally, each of the second and third semiconductor chip stack structures 602 and 603 may also be referred to as a memory die stack structure or a memory chip stack structure.

Each of the second and third semiconductor chips 200 and 300 may also be referred to as a middle core die or a middle core chip, and the fourth semiconductor chip 400 may also be referred to as a top core die or a top core chip.

The first semiconductor chip 100 may include a first substrate 110 having first and second surfaces 112 and 114 opposite to each other in the vertical direction, a first through electrode 120 extending through the first substrate 110, a first insulating interlayer and a second insulating interlayer 130 sequentially stacked in the vertical direction beneath the first surface 112 of the first substrate 110, a first conductive pad 150 beneath the second insulating interlayer 130, a first conductive connection member 190 beneath the first conductive pad 150, a first protective pattern structure 160 on the second surface 114 of the first substrate 110, a first through electrode 120 extending through the first substrate 110, and a second conductive pad 170 on the first protective pattern structure 160 and contacting an upper surface of the first through electrode 120.

The first substrate 110 may include a semiconductor material, e.g., silicon, germanium, silicon-germanium, or a III-V group compound semiconductor, e.g., GaP, GaAs, GaSb, etc. In example embodiments, the first substrate 110 may be a silicon-on-insulator (SOI) substrate or a germanium-on-insulator (GOI) substrate.

A circuit device, e.g., a logic device, may be formed beneath the first surface 112 of the first substrate 110. The circuit device may include circuit patterns, which may be covered by the first insulating interlayer.

The second insulating interlayer 130 may contain a first wiring structure 140 therein. The first wiring structure 140 may include, e.g., wirings, vias, contact plugs, etc., however, the first wiring structure 140 is shown as a single structure in FIG. 1 in order to avoid complexity of the drawing.

The first insulating interlayer and the second insulating interlayer 130 may include an oxide, e.g., silicon oxide or a low-k dielectric material, e.g., an oxide doped with carbon or fluorine. The wirings, the vias, the contact plugs may include a conductive material, e.g., a metal, a metal nitride, a metal silicide, etc.

The first conductive pad 150 may be disposed beneath the second insulating interlayer 130, and may contact the first wiring structure 140 to be electrically connected thereto. In example embodiments, a plurality of first conductive pads 150 may be spaced apart from each other in the horizontal direction.

In example embodiments, the first conductive pad 150 may include a first seed pattern and a first conductive pattern sequentially stacked in the vertical direction downwardly from the second insulating interlayer 130. The first seed pattern may include, e.g., titanium, titanium nitride, and the first conductive pattern may include, e.g., nickel, copper, gold, etc.

The first through electrode 120 may extend in the vertical direction in the first substrate 110, and a portion of the first through electrode 120 may protrude in the vertical direction to be at least partially surrounded by the first protective pattern structure 160. In example embodiments, a plurality of first through electrodes 120 may be spaced apart from each other in the horizontal direction. The first through electrode 120 may include a metal, e.g., copper, aluminum, etc.

In example embodiments, the first through electrode 120 may extend through the first protective pattern structure 160, the first substrate 110 and the first insulating interlayer to contact the first wiring structure 140, and may be electrically connected to the first conductive pad 150 through the first wiring structure 140.

Alternatively, the first through electrode 120 may extend through the first protective pattern structure 160, the first substrate 110, the first insulating interlayer and the second insulating interlayer 130 to contact the first conductive pad 150, and may be electrically connected thereto. Alternatively, the first through electrode 120 may extend through the first protective pattern structure 160 and the first substrate 110 to contact the circuit patterns composing the circuit device covered by the first insulating interlayer, and may be electrically connected to the first conductive pad 150 through the circuit patterns and the first wiring structure 140.

The first protective pattern structure 160 may be disposed on the second surface 114 of the first substrate 110, and may surround a portion of the first through electrode 120. In example embodiments, the first protective pattern structure 160 may include a first protective pattern and a second protective pattern stacked in the vertical direction on the second surface 114 of the first substrate 110. The first protective pattern may include an oxide, e.g., silicon oxide, and the second protective pattern may include an insulating nitride, e.g., silicon nitride.

The second conductive pad 170 may be electrically connected to the first conductive pad 150 via the first through electrode 120 and the first wiring structure 140. In example embodiments, a plurality of second conductive pads 170 may be spaced apart from each other in the horizontal direction.

In example embodiments, the second conductive pad 170 may include a second seed pattern and a second conductive pattern sequentially stacked in the vertical direction upwardly from the first through electrode 120 and the first protective pattern structure 160. The second seed pattern may include, e.g., titanium, titanium nitride, and the second conductive pattern may include, e.g., nickel, copper, gold, etc.

The first conductive connection member 190 may contact a lower surface of the first conductive pad 150. The first conductive connection member 190 may be, e.g., a conductive bump. The first conductive connection member 190 may include a metal, e.g., tin, or a solder, which may be a tin alloy such as tin/silver, tin/copper, tin/indium, tin/silver/copper, etc.

The second semiconductor chip 200 may include a second substrate 210 having first and second surfaces 212 and 214 opposite to each other in the vertical direction, a second through electrode 220 extending through the second substrate 210, a third insulating interlayer and a fourth insulating interlayer 230 sequentially stacked in the vertical direction beneath the first surface 212 of the second substrate 210, a third conductive pad 250 beneath the fourth insulating interlayer 230, a second conductive connection member 290 beneath the third conductive pad 250, a second protective pattern structure 260 on the second surface 214 of the second substrate 210, and a fourth conductive pad 270 on the second protective pattern structure 260 and contacting an upper surface of the second through electrode 220.

The second substrate 210 may include a semiconductor material, e.g., silicon, germanium, silicon-germanium, or a III-V group compound semiconductor, e.g., GaP, GaAs, GaSb, etc. In example embodiments, the second substrate 210 may be a silicon-on-insulator (SOI) substrate or a germanium-on-insulator (GOI) substrate.

A circuit device, e.g., a memory device, may be formed beneath the first surface 212 of the second substrate 210. The circuit device may include circuit patterns, which may be covered by the third insulating interlayer.

The fourth insulating interlayer 230 may contain a second wiring structure 240 therein. The second wiring structure 240 may include, e.g., wirings, vias, contact plugs, etc., however, the second wiring structure 240 is shown as a single structure in FIG. 1 in order to avoid complexity of the drawing.

The third insulating interlayer and the fourth insulating interlayer 230 may include an oxide, e.g., silicon oxide or a low-k dielectric material, e.g., an oxide doped with carbon or fluorine. The wirings, the vias, the contact plugs may include a conductive material, e.g., a metal, a metal nitride, a metal silicide, etc.

The third conductive pad 250 may be disposed beneath the fourth insulating interlayer 230, and may contact the second wiring structure 240 to be electrically connected thereto. In example embodiments, a plurality of third conductive pads 250 may be spaced apart from each other in the horizontal direction.

In example embodiments, the third conductive pad 250 may include a third seed pattern and a third conductive pattern sequentially stacked in the vertical direction downwardly from the fourth insulating interlayer 230. The third seed pattern may include, e.g., titanium, titanium nitride, and the third conductive pattern may include, e.g., nickel, copper, gold, etc.

The second through electrode 220 may extend in the vertical direction in the second substrate 210, and a portion of the second through electrode 220 may protrude in the vertical direction to be at least partially surrounded by the second protective pattern structure 260. In example embodiments, a plurality of second through electrodes 220 may be spaced apart from each other in the horizontal direction. The second through electrode 220 may include a metal, e.g., copper, aluminum, etc.

In example embodiments, the second through electrode 220 may extend through the second protective pattern structure 260, the second substrate 210 and the third insulating interlayer to contact the second wiring structure 240, and may be electrically connected to the third conductive pad 250 through the second wiring structure 240.

Alternatively, the second through electrode 220 may extend through the second protective pattern structure 260, the second substrate 210, the third insulating interlayer and the fourth insulating interlayer 230 to contact the third conductive pad 250, and may be electrically connected thereto. Alternatively, the second through electrode 220 may extend through the second protective pattern structure 260 and the second substrate 210 to contact the circuit patterns composing the circuit device covered by the third insulating interlayer, and may be electrically connected to the third conductive pad 250 through the circuit patterns and the second wiring structure 240.

The second protective pattern structure 260 may be disposed on the second surface 214 of the second substrate 210, and may surround a portion of the second through electrode 220. In example embodiments, the second protective pattern structure 260 may include a third protective pattern and a fourth protective pattern stacked in the vertical direction on the second surface 214 of the second substrate 210. The third protective pattern may include an oxide, e.g., silicon oxide, and the fourth protective pattern may include an insulating nitride, e.g., silicon nitride.

The fourth conductive pad 270 may be electrically connected to the third conductive pad 250 via the second through electrode 220 and the second wiring structure 240. In example embodiments, a plurality of fourth conductive pads 270 may be spaced apart from each other in the horizontal direction.

In example embodiments, the fourth conductive pad 270 may include a fourth seed pattern and a fourth conductive pattern sequentially stacked in the vertical direction upwardly from the second through electrode 220 and the second protective pattern structure 260. The fourth seed pattern may include, e.g., titanium, titanium nitride, and the fourth conductive pattern may include, e.g., nickel, copper, gold, etc.

The second conductive connection member 290 may be disposed between and contact the second and third conductive pads 170 and 250. The second conductive connection member 290 may be, e.g., a conductive bump. The second conductive connection member 290 may include a metal, e.g., tin, or a solder.

The first adhesion layer 710 may be disposed between the first and second semiconductor chips 100 and 200, and bond the first and second semiconductor chips 100 and 200 with each other. The first adhesion layer 710 may surround the second and third conductive pads 170 and 250 and the second conductive connection member 290 (or may surround side surfaces thereof). The first adhesion layer 710 may include, e.g., non-conductive film (NCF).

In example embodiments, the first semiconductor chip 100 may have a first planar area, the second semiconductor chip 200 may have a second planar area smaller than the first planar area, and an edge portion of the first semiconductor chip 100 may not overlap the second semiconductor chip 200 in the vertical direction. A portion of the first adhesion layer 710 may protrude in the horizontal direction aside or away from a sidewall or side surface of the second semiconductor chip 200, and may contact a lower sidewall or lower surface of the second semiconductor chip 200. The portion of the first adhesion layer 710 may be disposed on the edge portion of the first semiconductor chip 100 not overlapping the second semiconductor chip 200 in the vertical direction.

In example embodiments, the third semiconductor chip 300 may have a structure substantially the same as or similar to that of the second semiconductor chip 200, and thus the third semiconductor chip 300 is only briefly described.

The third semiconductor chip 300 may include a third substrate 310 having first and second surfaces 312 and 314 opposite to each other in the vertical direction, a third through electrode 320 extending through the third substrate 310, a fifth insulating interlayer and a sixth insulating interlayer 330 sequentially stacked in the vertical direction beneath the first surface 312 of the third substrate 310, a fifth conductive pad 350 beneath the sixth insulating interlayer 330, a third conductive connection member 390 beneath the fifth conductive pad 350, a third protective pattern structure 360 on the second surface 314 of the third substrate 310, and a sixth conductive pad 370 on the third protective pattern structure 360 and contacting an upper surface of the third through electrode 320.

A circuit device, e.g., a memory device, may be formed beneath the first surface 312 of the third substrate 310. The circuit device may include circuit patterns, which may be covered by the fifth insulating interlayer. The sixth insulating interlayer 330 may contain a third wiring structure 340 therein.

The fifth conductive pad 350 may be disposed beneath the sixth insulating interlayer 330, and may contact the third wiring structure 340 to be electrically connected thereto. In example embodiments, a plurality of fifth conductive pads 350 may be spaced apart from each other in the horizontal direction.

In example embodiments, the fifth conductive pad 350 may include a fifth seed pattern and a fifth conductive pattern sequentially stacked in the vertical direction downwardly from the sixth insulating interlayer 330.

The third through electrode 320 may extend in the vertical direction in the third substrate 310, and a portion of the third through electrode 320 may protrude in the vertical direction to be at least partially surrounded by the third protective pattern structure 360. In example embodiments, a plurality of third through electrodes 320 may be spaced apart from each other in the horizontal direction.

In example embodiments, the third through electrode 320 may extend through the third protective pattern structure 360, the third substrate 310 and the fifth insulating interlayer to contact the third wiring structure 340, and may be electrically connected to the fifth conductive pad 350 through the third wiring structure 340.

The third protective pattern structure 360 may be disposed on the second surface 314 of the third substrate 310, and may surround a portion of the third through electrode 320. In example embodiments, the third protective pattern structure 360 may include a fifth protective pattern and a sixth protective pattern stacked in the vertical direction on the second surface 314 of the third substrate 310.

The sixth conductive pad 370 may be electrically connected to the fifth conductive pad 350 via the third through electrode 320 and the third wiring structure 340. In example embodiments, the sixth conductive pad 370 may include a sixth seed pattern and a sixth conductive pattern sequentially stacked in the vertical direction upwardly from the third through electrode 320 and the third protective pattern structure 360.

The third conductive connection member 390 may be disposed between and contact the fourth and fifth conductive pads 270 and 350.

The second adhesion layer 720 may be disposed between the second and third semiconductor chips 200 and 300, and bond the second and third semiconductor chips 200 and 300 with each other. The second adhesion layer 720 may surround the third and sixth conductive pads 250 and 370 and the second conductive connection member 290 (or may surround side surfaces thereof). The second adhesion layer 720 may include, e.g., NCF.

In example embodiments, the third semiconductor chip 300 may have a third planar area, which may be greater than the second planar area of the second semiconductor chip 200 and smaller than the first planar area of the first semiconductor chip 100. An edge portion of the third semiconductor chip 300 may not overlap the second semiconductor chip 200 in the vertical direction.

A portion of the second adhesion layer 720 may protrude in the horizontal direction aside or away from the sidewall or side surface of the second semiconductor chip 200, and may contact the lower sidewall or lower surface of the second semiconductor chip 200. The portion of the second adhesion layer 720 may be disposed on the edge portion of the third semiconductor chip 300 not overlapping the second semiconductor chip 200 in the vertical direction.

In example embodiments, the fourth semiconductor chip 400 may have a structure substantially the same as or similar to that of the second semiconductor chip 200, and thus the fourth semiconductor chip 400 is only briefly described.

The fourth semiconductor chip 400 may include a fourth substrate 410 having first and second surfaces 412 and 414 opposite to each other in the vertical direction, a seventh insulating interlayer and an eighth insulating interlayer 430 sequentially stacked in the vertical direction beneath the first surface 412 of the fourth substrate 410, a seventh conductive pad 450 beneath the eighth insulating interlayer 430, and a fourth conductive connection member 490 beneath the seventh conductive pad 450.

A circuit device, e.g., a memory device, may be formed beneath the first surface 412 of the fourth substrate 410. The circuit device may include circuit patterns, which may be covered by the seventh insulating interlayer. The eighth insulating interlayer 430 may contain a fourth wiring structure 440 therein.

The seventh conductive pad 450 may be disposed beneath the eighth insulating interlayer 430, and may contact the fourth wiring structure 440 to be electrically connected thereto. In example embodiments, a plurality of seventh conductive pads 450 may be spaced apart from each other in the horizontal direction.

In example embodiments, the seventh conductive pad 450 may include a seventh seed pattern and a seventh conductive pattern sequentially stacked in the vertical direction downwardly from the eighth insulating interlayer 430.

The fourth conductive connection member 490 may be disposed between and contact the sixth and seventh conductive pads 370 and 450.

The third adhesion layer 730 may be disposed between the third and fourth semiconductor chips 300 and 400, and bond the third and fourth semiconductor chips 300 and 400 with each other. The third adhesion layer 730 may surround the sixth and seventh conductive pads 370 and 450 and the fourth conductive connection member 490 (or surround side surfaces thereof). The third adhesion layer 730 may include, e.g., NCF.

In example embodiments, the fourth semiconductor chip 400 may have a fourth planar area, which may be substantially the same as the second planar area of the second semiconductor chip 200. Thus, the fourth planar area of the fourth semiconductor chip 400 may be smaller than the third planar area of the third semiconductor chip 300, and an edge portion of the third semiconductor chip 300 may not overlap the fourth semiconductor chip 400 in the vertical direction.

A portion of the third adhesion layer 730 may protrude in the horizontal direction aside or away from the sidewall or side surface of the fourth semiconductor chip 400, and may contact a lower sidewall or lower surface of the fourth semiconductor chip 400. The portion of the fourth adhesion layer 730 may be disposed on the edge portion of the third semiconductor chip 300 not overlapping the fourth semiconductor chip 400 in the vertical direction.

The molding member 500 may be disposed on the first semiconductor chip 100, and may at least partially cover the second semiconductor chip 200 and the first adhesion layer 710 of the first semiconductor chip stack structure 601, and sidewalls of the second and third semiconductor chip stack structures 602 and 603, and a vertical level of an upper surface of the molding member 500 may be substantially the same as that of an upper surface of the fourth semiconductor chip 400 of the third semiconductor chip stack structure 603. The upper surface of the molding member 500 may be coplanar with the upper surface of the fourth semiconductor chip 400. The molding member 500 may include a polymer, e.g., epoxy molding compound (EMC).

In the semiconductor package according to example embodiments, the first and second semiconductor chips 100 and 200, the third and second semiconductor chips 300 and 200, and the third and fourth semiconductor chips 300 and 400 sequentially stacked in the first to third semiconductor chip stack structures 601, 602 and 603, respectively, may be bonded with or to each other by the second conductive connection member 290, the second conductive connection member 290 and the fourth conductive connection member 490, respectively, together with the first to third adhesion layers 710, 720 and 730, respectively.

The first and second semiconductor chip stack structures 601 and 602, and the second and third semiconductor chip stack structures 602 and 603 may be bonded with each other by the third conductive connection member 390.

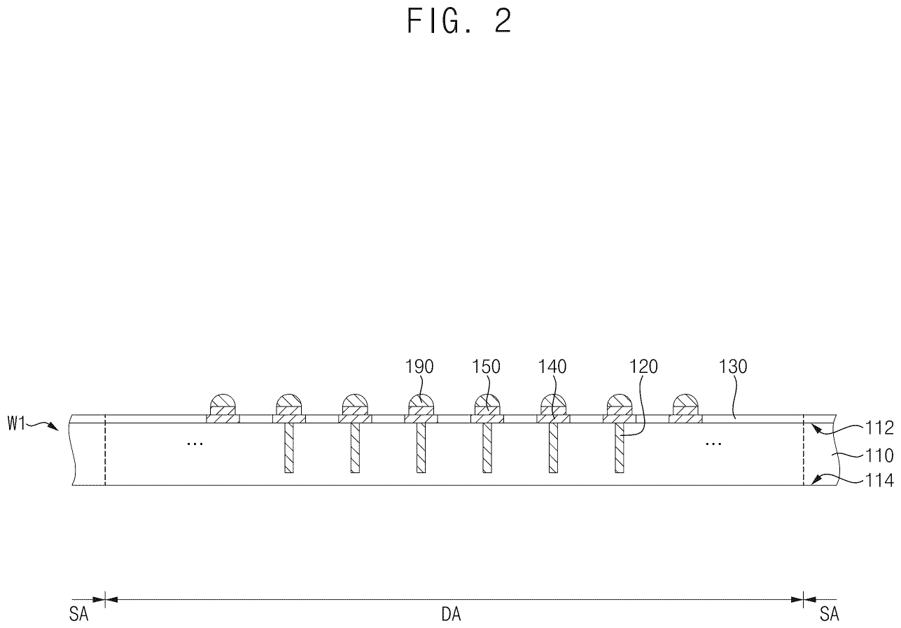

As illustrated below with reference to FIGS. 2 to 11, for example, instead of stacking the second to fourth semiconductor chips 200, 300 and 400 on the first semiconductor chip 100 and performing a mass reflow process to simultaneously bond the second to fourth semiconductor chips 200, 300 and 400, after bonding the third semiconductor chip 300 and the second semiconductor chip 200 to form a pair using the second conductive connection member 290 and the second adhesion layer 720, the first to third semiconductor chip stack structures 601, 602 and 603 may be bonded by a mass reflow process.

Thus, even if each of the second and third semiconductor chips 200 and 300 has a thin thickness, the second semiconductor chip stack structure 602 including the second and third semiconductor chips 200 and 300 bonded with each other may have an increased thickness, so that warpage of the second and third semiconductor chips 200 and 300 may be prevented or reduced when the first to third semiconductor chip stack structures 601, 602 and 603 are bonded with each other.

Accordingly, electrical connections between the first to third semiconductor chip stack structures 601, 602 and 603, and electrical connections between the first and second semiconductor chips 100 and 200, between the second and third semiconductor chips 200 and 300, and between the third and fourth semiconductor chips 300 and 400 may be enhanced, and the semiconductor package including the first to third semiconductor chip stack structures 601, 602 and 603 may have enhanced electrical characteristics.

FIGS. 2 to 11 are cross-sectional views illustrating a method of manufacturing a semiconductor package in accordance with example embodiments.

Referring to FIG. 2, a first wafer W1 may be provided.

In example embodiments, the first wafer W1 may include a first substrate 110 having first and second surfaces 112 and 114 opposite to each other in the vertical direction. Additionally, the first wafer W1 may include a plurality of die regions DA and a scribe lane region SA surrounding each of the die regions DA. The first wafer W1 may be cut along the scribe lane region SA by a sawing process to be singulated into a plurality of first semiconductor chips.

In the die region DA, a circuit device may be formed beneath the first surface 112 of the first substrate 110. The circuit device may include a logic device. The circuit device may include circuit patterns, and a first insulating interlayer may be formed beneath the first surface 112 of the first substrate 110 to cover the circuit patterns.

A second insulating interlayer 130 may be formed beneath the first insulating interlayer, and may contain a first wiring structure 140 therein.

A first conductive pad 150 may be formed on the second insulating interlayer 130, and may contact the first wiring structure 140 to be electrically connected thereto. In example embodiments, the first conductive pad 150 may be formed by following processes.

Particularly, a first seed layer may be formed on the second insulating interlayer 130, a first photoresist pattern including a first opening partially exposing an upper surface of the first seed layer may be formed on the first seed layer, and for example, an electroplating process or an electroless plating process may be performed to form a first conductive pattern in the first opening.

The first photoresist pattern may be removed by, e.g., an ashing process and/or a stripping process to expose a portion of the first seed layer, the exposed portion of the first seed layer may be removed to form a first seed pattern under the first conductive pattern. Thus, a first conductive pad 150 including the first seed pattern and the first conductive pattern sequentially stacked in the vertical direction may be formed.

A first conductive connection member 190 may be formed on the first conductive pad 150, for example as follows.

Particularly, a second photoresist pattern including a second opening exposing an upper surface of the first conductive pad 150 may be formed on the second insulating interlayer 130, and for example, an electroplating process or an electroless plating process may be performed to form a preliminary first conductive connection member in the second opening. After removing the second photoresist pattern, a reflow process may be performed so that the preliminary first conductive connection member may be transformed into the first conductive connection member 190.

In example embodiments, the first conductive connection member 190 may have, e.g., a hemispherical shape or a semioval shape.

In example embodiments, the first substrate 110 may include a first through electrode 120 extending through an upper portion of the first substrate 110, that is, a portion of the first substrate 110 adjacent to the first surface 112 and contacting the first wiring structure 140 to be electrically connected thereto.

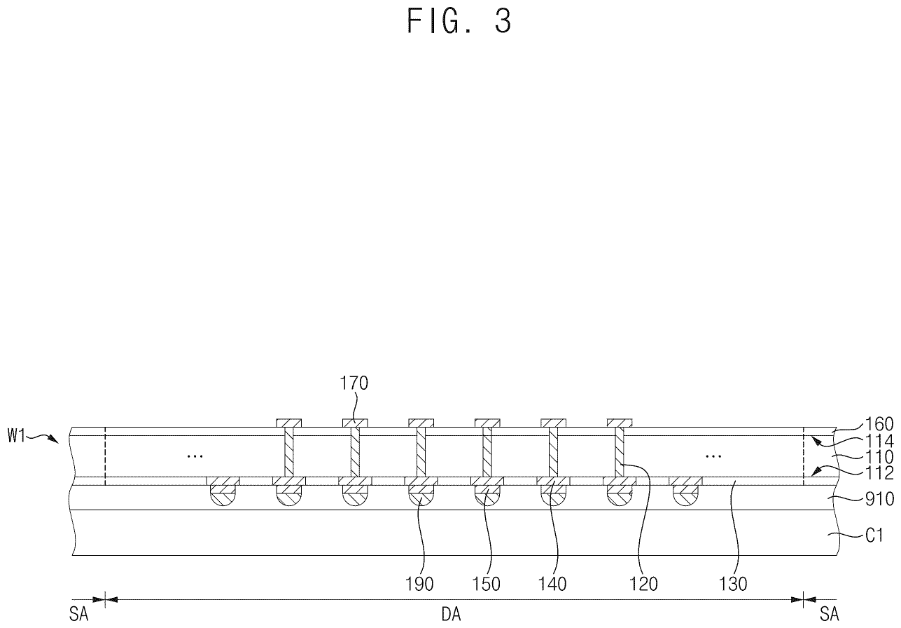

Referring to FIG. 3, a first temporary adhesion layer 910 may be attached to a first carrier substrate C1, and the first carrier substrate C1 may be bonded with the first wafer W1 by attaching the first temporary adhesion layer 910 to an upper surface of the second insulating interlayer 130 in which the first wiring structure 140 is formed to cover the first conductive connection member 190 and the first conductive pad 150.

The first temporary adhesion layer 910 may include a material losing adhesion by irradiation of light such as ultraviolet (UV) light or heat. For example, the first temporary adhesion layer 910 may include glue.

After flipping the first wafer W1, a portion of the first substrate 110 adjacent to the second surface 114 of the first substrate 110 may be removed by, e.g., a grinding process to expose an upper portion of the first through electrode 120.

A first protective layer structure may be formed on the second surface 114 of the first substrate 110 to cover the first through electrode 120, and a planarization process may be performed on the first protective layer structure until an upper surface of the first through electrode 120 is exposed to form a first protective pattern structure 160.

In example embodiments, the planarization process may include a chemical mechanical polishing (CMP) process and/or an etch back process.

A second conductive pad 170 may be formed on the first protective pattern structure 160 and the first through electrode 120. In example embodiments, the second conductive pad 170 may contact the upper surface of the first through electrode 120 to be electrically connected thereto. In example embodiments, the second conductive pad 170 may be formed by following processes.

Particularly, a second seed layer may be formed on the first protective pattern structure 160 and the first through electrode 120, a third photoresist pattern including a third opening partially exposing an upper surface of the second seed layer may be formed on the second seed layer, and for example, an electroplating process or an electroless plating process may be performed to form a second conductive pattern in the third opening.

After removing the third photoresist pattern by, e.g., an ashing process and/or a stripping process to expose a portion of the second seed layer, the exposed portion of the second seed layer may be removed to form a second seed pattern under the second conductive pattern. Thus, a second conductive pad 170 including a second seed pattern and a second conductive pattern sequentially stacked in the vertical direction may be formed.

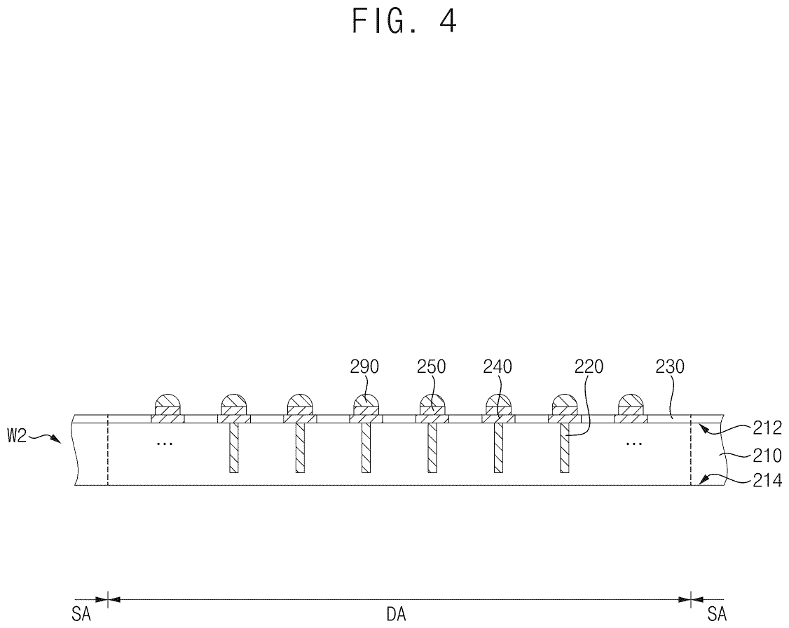

Referring to FIG. 4, a second wafer W2 may be provided.

In example embodiments, the second wafer W2 may include a second substrate 210 having first and second surfaces 212 and 214 opposite to each other in the vertical direction. Additionally, the second wafer W2 may include a plurality of die regions DA and a scribe lane region SA surrounding each of the die regions DA. The second wafer W2 may be cut along the scribe lane region SA by a sawing process to be singulated into a plurality of second semiconductor chips.

In the die region DA, a circuit device may be formed beneath the first surface 212 of the second substrate 210. The circuit device may include a memory device. The circuit device may include circuit patterns, and a third insulating interlayer may be formed beneath the first surface 212 of the second substrate 210 to cover the circuit patterns.

A fourth insulating interlayer 230 may be formed on the third insulating interlayer, and may contain a second wiring structure 240 therein.

A third conductive pad 250 may be formed on the fourth insulating interlayer 230, and may contact the second wiring structure 240 to be electrically connected thereto. The third conductive pad 250 may include a third seed pattern and a third conductive pattern sequentially stacked in the vertical direction.

A second conductive connection member 290 may be formed on the third conductive pad 250, and may have, e.g., a hemispherical shape or a semioval shape.

In example embodiments, a second through electrode 220 may extend through an upper portion of the second substrate 210, that is, a portion of the second substrate 210 adjacent to the first surface 212, and may contact the second wiring structure 240 to be electrically connected thereto.

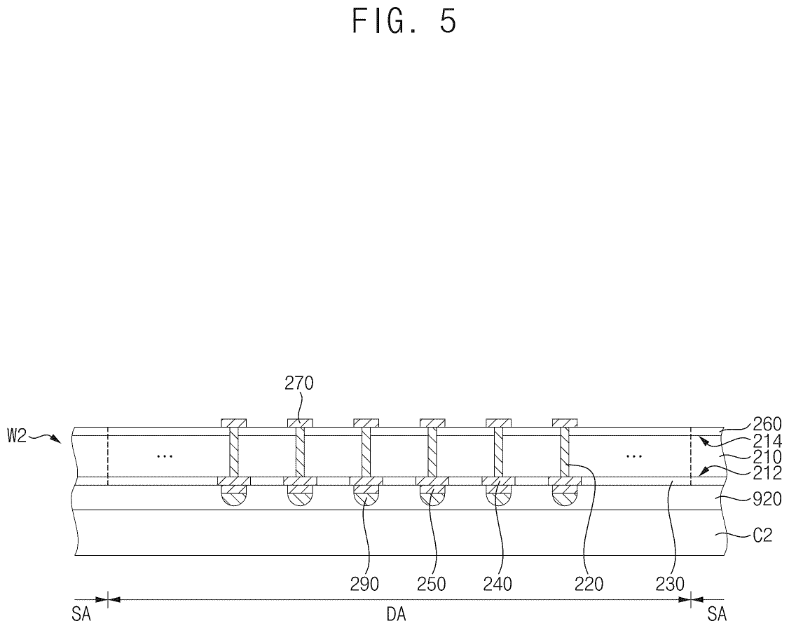

Referring to FIG. 5, a second temporary adhesion layer 920 may be attached to a second carrier substrate C2, and the second carrier substrate C2 may be bonded with the second wafer W2 by attaching the second temporary adhesion layer 920 to an upper surface of the fourth insulating interlayer 230 in which the second wiring structure 240 is formed to cover the second conductive connection member 290 and the third conductive pad 250.

The second temporary adhesion layer 920 may include a material losing adhesion by irradiation of light such as ultraviolet (UV) light or heat. For example, the second temporary adhesion layer 920 may include glue.

After flipping the second wafer W2, a portion of the second substrate 210 adjacent to the second surface 214 of the second substrate 210 may be removed by, e.g., a grinding process to expose an upper portion of the second through electrode 220.

A second protective layer structure may be formed on the second surface 214 of the second substrate 210 to cover the second through electrode 220, and a planarization process may be performed on the second protective layer structure until an upper surface of the second through electrode 220 is exposed to form a second protective pattern structure 260.

A fourth conductive pad 270 may be formed on the second protective pattern structure 260 and the second through electrode 220. In example embodiments, the fourth conductive pad 270 may contact the upper surface of the second through electrode 220 to be electrically connected thereto. In example embodiments, the fourth conductive pad 270 may include a fourth seed pattern and a fourth conductive pattern sequentially stacked in the vertical direction.

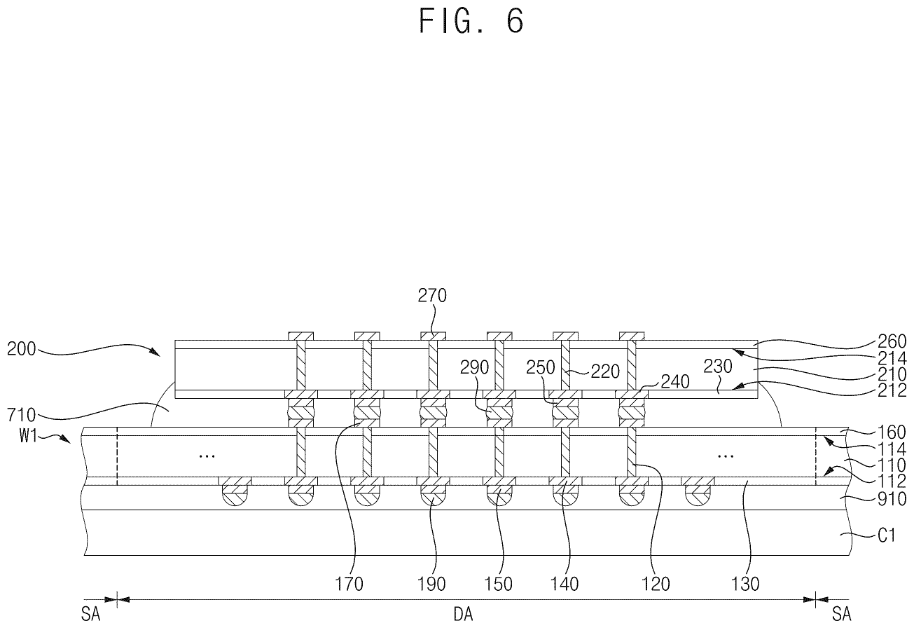

Referring to FIG. 6, after flipping the second wafer W2, the second wafer W2 may be attached to an upper surface of a release tape on a frame having, e.g., a ring shape.

The second temporary adhesion layer 920 attached to the second carrier substrate C2 may be separated from the second conductive connection member 290, the third conductive pad 250 and the fourth insulating interlayer 230 so that the second carrier substrate C2 may be separated from the second wafer W2.

The second wafer W2 may be cut along the scribe lane region SA by, e.g., a sawing process to be singulated into a plurality of second semiconductor chips 200, and a first adhesion layer 710 may be attached to the fourth insulating interlayer 230 of each of the second semiconductor chips 200.

The first adhesion layer 710 may be formed on the fourth insulating interlayer 230 to cover or surround the third conductive pad 250 and the second conductive connection member 290 (or side surfaces thereof).

In some embodiments, before the sawing process, the first adhesion layer 710 may be formed on the fourth insulating interlayer 230 of the second wafer W2.

Each of the second semiconductor chips 200 may be separated from the release tape, and picked up from the frame. Each of the second semiconductor chips 200 may be mounted onto the first wafer W1 by attaching the first adhesion layer 710 attached to the second semiconductor chip 200 to an upper surface of the first protective pattern structure 160 of the first wafer W1. The second semiconductor chips 200 may be arranged on the first wafer W1 so as to correspond to the die regions DA, respectively, and the second conductive connection member 290 of the second semiconductor chip 200 may contact an upper surface of a corresponding one of the second conductive pads 170 of the first wafer W1.

A thermal compression bonding (TCB) process may be performed at a temperature of, e.g., equal to or less than about 400° C. so that the second semiconductor chips 200 may be bonded to the first wafer W1. During the TCB process, the first conductive connection member 290 of the second semiconductor chip 200 may be bonded with the upper surface of the corresponding one of the second conductive pads 170 of the first wafer W1.

Additionally, during the TCB process, the NCF included in the first adhesion layer 710 may be liquefied to flow into a space between the second semiconductor chips 200 and the first wafer W1, and fill the space after being cured. A portion of the cured first adhesion layer 710 may protrude in the horizontal direction aside or away from a sidewall or side surface of each of the second semiconductor chips 200, and thus the first adhesion layer 710 may also be formed on a portion of the first wafer W1 not overlapping the second semiconductor chip 200 in the vertical direction.

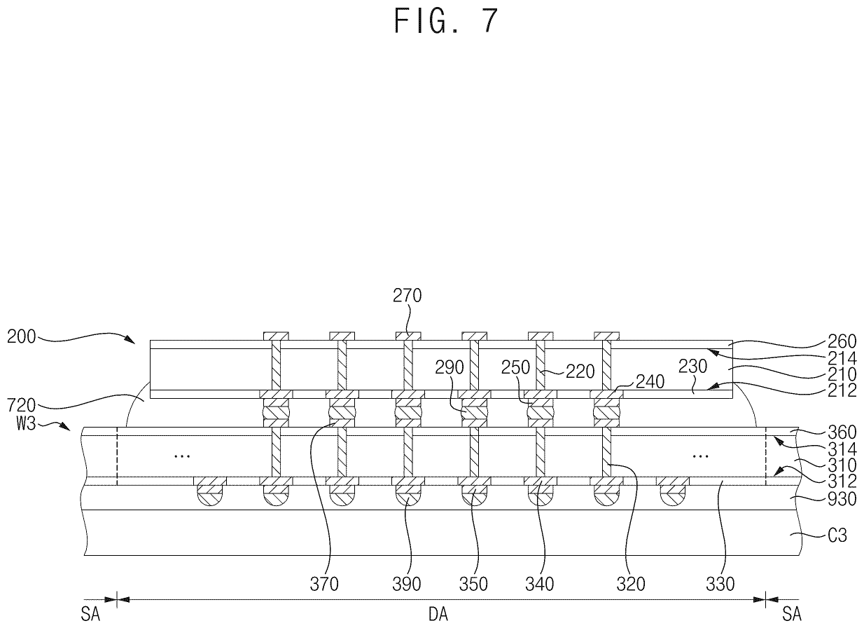

Referring to FIG. 7, processes substantially the same as or similar to those illustrated with respect to FIGS. 2 to 6 may be performed so that each of the second semiconductor chips 200 may be mounted onto the third wafer W3.

In example embodiments, the third wafer W3 may include a third substrate 310 having first and second surfaces 312 and 314 opposite to each other in the vertical direction. Additionally, the third wafer W3 may include a plurality of die regions DA and a scribe lane region SA surrounding each of the die regions DA. The third wafer W3 may be cut along the scribe lane region SA by a sawing process to be singulated into a plurality of third semiconductor chips.

In the die region DA, a circuit device may be formed beneath the first surface 312 of the third substrate 310. The circuit device may include a memory device. The circuit device may include circuit patterns, and a fifth insulating interlayer may be formed beneath the first surface 312 of the third substrate 310 to cover the circuit patterns.

A sixth insulating interlayer 330 may be formed beneath the fifth insulating interlayer, and may contain a third wiring structure 340 therein.

A fifth conductive pad 350 may be formed on the sixth insulating interlayer 330, and may contact the third wiring structure 340 to be electrically connected thereto. The fifth conductive pad 350 may include a fifth seed pattern and a fifth conductive pattern sequentially stacked in the vertical direction.

A third conductive connection member 390 may be formed beneath the fifth conductive pad 350, and may have, e.g., a hemispherical shape or a semioval shape.

In example embodiments, a third through electrode 320 may extend through the third substrate 310, and may contact the third wiring structure 340 to be electrically connected thereto.

A third protective pattern structure 360 may be disposed on the second surface 314 of the third substrate 310, and may surround an upper sidewall of the third through electrode 320. A sixth conductive pad 370 may be disposed on the third protective pattern structure 360, and may contact an upper surface of the third through electrode 320 to be electrically connected thereto. The sixth conductive pad 370 may include a sixth seed pattern and a sixth conductive pattern sequentially stacked in the vertical direction upwardly from the third through electrode 320 and the third protective pattern structure 360.

A second adhesion layer 720 may be disposed between each of the second semiconductor chips 200 and the third wafer W3, and may cover or surround the third and sixth conductive pads 250 and 370 (or side surfaces thereof). In an example embodiment, a portion of the second adhesion layer 720 may protrude in the horizontal direction aside or away from the sidewall or side surface of each of the second semiconductor chips 200, and thus the second adhesion layer 720 may also be formed on a portion of the third wafer W3 not overlapping the second semiconductor chip 200 in the vertical direction.

A third temporary adhesion layer 930 may be formed beneath a lower surface of the sixth insulating interlayer 330 containing the third wiring structure 340 therein, and cover the third conductive connection member 390 and the fifth conductive pad 350. A third carrier substrate C3 may be disposed beneath a lower surface of the third temporary adhesion layer 930.

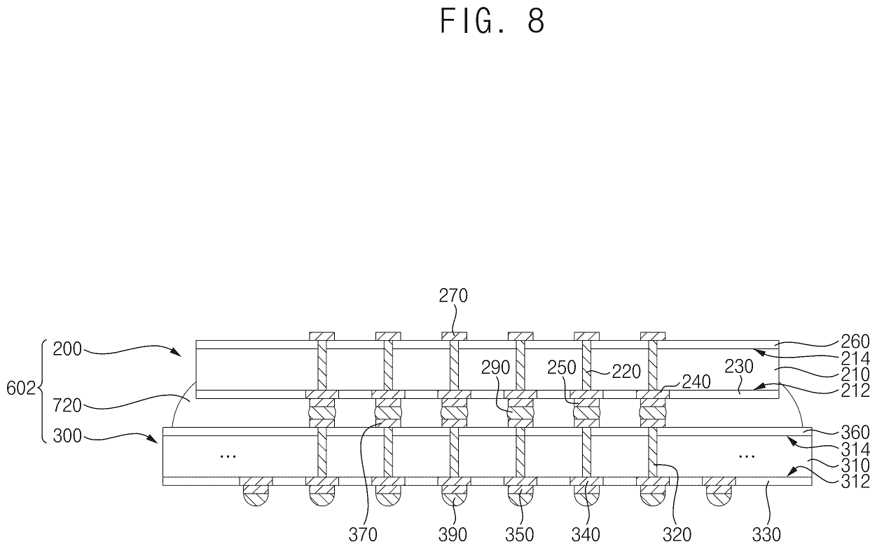

Referring to FIG. 8, the third wafer W3 may be cut along the scribe lane region SA by, e.g., a sawing process to be singulated into a plurality of third semiconductor chips 300, and the second semiconductor chip 200 may be bonded with each of the third semiconductor chips 300 to form a second semiconductor chip stack structure 602.

The third temporary adhesion layer 930 and the third carrier substrate C3 may be separated from the third wafer W3.

In example embodiments, each of the third semiconductor chips 300 may have a planar area greater than a planar area of the second semiconductor chip 200 bonded thereto, and thus an edge portion of each of the third semiconductor chips 300 may not overlap the second semiconductor chip 200 in the vertical direction. The portion of the second adhesion layer 720 protruding in the horizontal direction aside or away from the sidewall or side surface of the second semiconductor chip 200 may be formed on the edge portion of the third semiconductor chip 300.

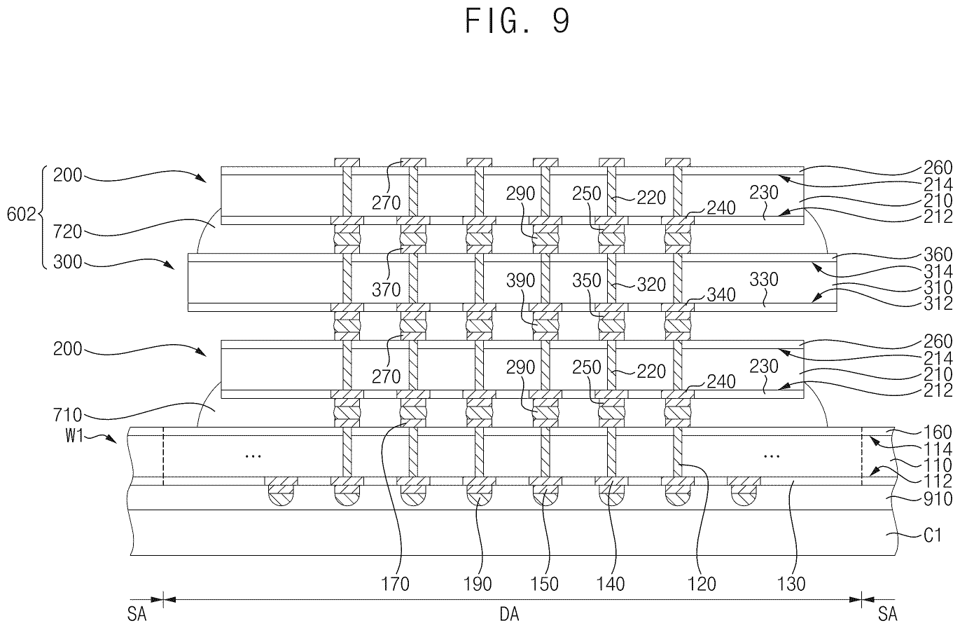

Referring to FIG. 9, the second semiconductor chip stack structure 602 may be mounted onto the second semiconductor chip 200 bonded with the first wafer W1.

That is, the third conductive connection member 390 of the third semiconductor chip 300 included in the second semiconductor chip stack structure 602 may contact an upper surface of the fourth conductive pad 270 of the second semiconductor chip 200 bonded with the first wafer W1 so that the second semiconductor chip stack structure 602 may be bonded with the first wafer W1.

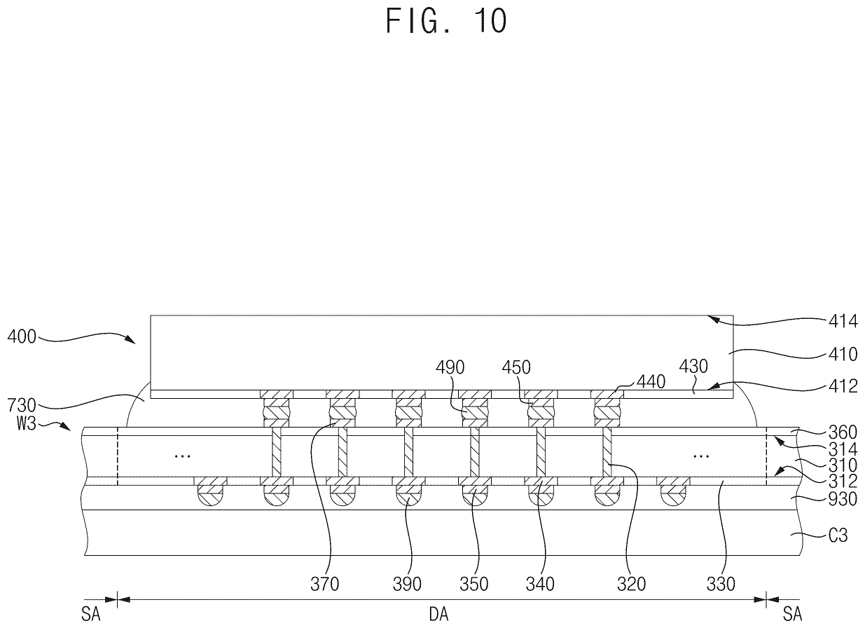

Referring to FIG. 10, processes substantially the same as or similar to those illustrated and described with respect to FIG. 7 may be performed so that each of a plurality of fourth semiconductor chips 400 may be bonded with the third wafer W3 by a TCB process.

In example embodiments, the fourth semiconductor chip 400 may include a fourth substrate 410 having first and second surfaces 412 and 414 opposite to each other in the vertical direction, and a circuit device, e.g., a memory device, may be formed beneath the first surface 412 of the fourth substrate 410. The circuit device may include circuit patterns, which may be covered by a seventh insulating interlayer.

An eighth insulating interlayer 430 may be disposed beneath the seventh insulating interlayer, and may contain a fourth wiring structure 440 therein.

A seventh conductive pad 450 may be disposed beneath the eighth insulating interlayer 430, and may contact the fourth wiring structure 440 to be electrically connected thereto. In example embodiments, the seventh conductive pad 450 may include a seventh seed pattern and a seventh conductive pattern sequentially stacked in the vertical direction.

A fourth conductive connection member 490 may be disposed beneath the seventh conductive pad 450, and may have, e.g., a hemispherical shape or a semioval shape.

A third adhesion layer 730 may be disposed between each of the fourth semiconductor chips 400 and the third wafer W3, and may cover or surround the sixth and seventh conductive pads 370 and 450 and the fourth conductive connection member 490 (or side surfaces thereof). In example embodiments, a portion of the third adhesion layer 730 may protrude in the horizontal direction aside or away from the sidewall or side surface of each of the fourth semiconductor chips 400, and thus the third adhesion layer 730 may also be formed on a portion of the third wafer W3 not overlapping the fourth semiconductor chip 400 in the vertical direction.

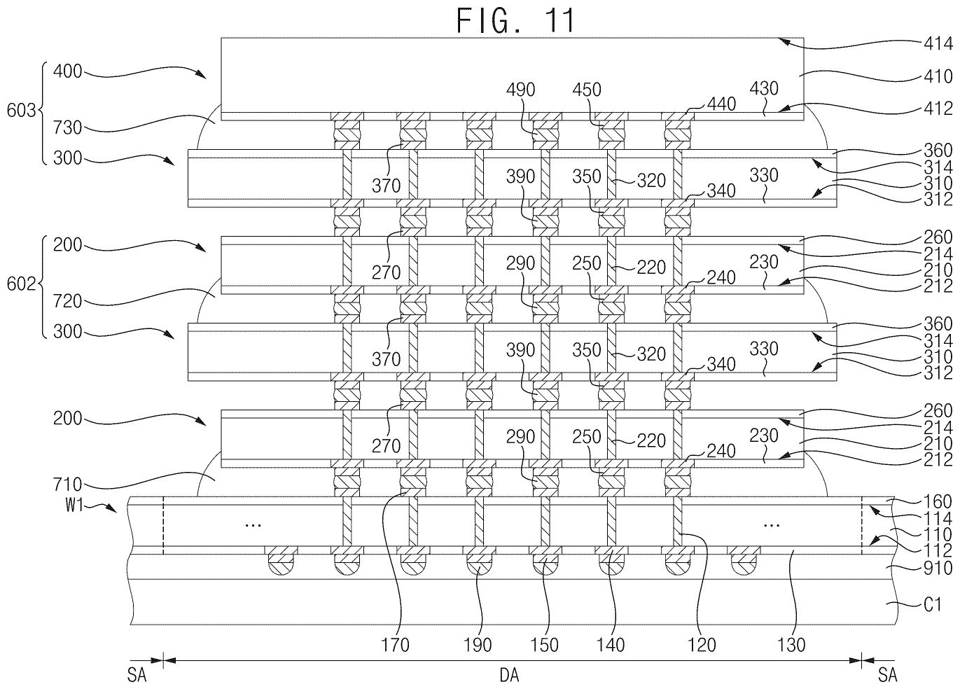

Referring to FIG. 11, processes substantially the same as or similar to those illustrated with respect to FIGS. 8 and 9 may be performed.

That is, the third wafer W3 may be cut along the scribe lane region SA by, e.g., a sawing process, to be singulated into a plurality of third semiconductor chips 300, and the fourth semiconductor chip 400 may be bonded with each of the third semiconductor chips 300 to form a third semiconductor chip stack structure 603.

In example embodiments, each of the third semiconductor chips 300 may have a planar area greater than a planar area of the fourth semiconductor chip 400 bonded thereto, and thus an edge portion of each of the third semiconductor chips 300 may not overlap the fourth semiconductor chip 400 in the vertical direction. The portion of the third adhesion layer 730 protruding in the horizontal direction aside or away from the sidewall or side surface of the fourth semiconductor chip 400 may be formed on the edge portion of the third semiconductor chip 300.

The third semiconductor chip stack structure 603 may be mounted onto the second semiconductor chip 200 included in the second semiconductor chip stack structure 602 bonded with the first wafer W1. That is, the third conductive connection member 390 of the third semiconductor chip 300 included in the third semiconductor chip stack structure 603 may contact an upper surface of the fourth conductive pad 270 of the second semiconductor chip 200 included in the second semiconductor chip stack structure 602 so that the third semiconductor chip stack structure 603 may be bonded with the second semiconductor chip stack structure 602.

Referring to FIG. 1 again, a mass reflow process may be performed by heating the first wafer W1, and thus the third conductive connection member 390 between the second semiconductor chip 200 bonded with the first wafer W1 and the second semiconductor chip stack structure 602, and the third conductive connection member 390 between the second and third semiconductor chip stack structures 602 and 603 may be liquefied and then solidified, so that the second semiconductor chip 200 and the second semiconductor chip stack structure 602 may be bonded with each other and the second and third semiconductor chip stack structures 602 and 603 may be bonded with each other.

A molding member 500 may be formed on the first wafer W1 to cover sidewalls or side surfaces of the second semiconductor chip 200, the second and third semiconductor chip stack structures 602 and 603, and the first to third adhesion layers 710, 720 and 730, and may at least partially fill a space between the second semiconductor chip 200 bonded with the first wafer W1 and the second semiconductor chip stack structure 602 and a space between the second and third semiconductor chip stack structures 602 and 603.

In example embodiments, the molding member 500 may expose an upper surface of the fourth semiconductor chip 400.

The first wafer W1 may be cut along the scribe lane region SA by, e.g., a sawing process, to be singulated into a plurality of first semiconductor chips 100, and the second semiconductor chip 200 may be bonded with each of the first semiconductor chips 100 to form a first semiconductor chip stack structure 601.

During the sawing process, the molding member 500 may also be cut to be formed on each of the first semiconductor chips 100.

The first temporary adhesion layer 910 and the first carrier substrate C1 may be separated from each of the first semiconductor chips 100 to complete the manufacturing the semiconductor package.

In example embodiments, a single second semiconductor chip stack structure 602 may be disposed between the first semiconductor chip stack structure 601 and the third semiconductor chip stack structure 603, however, the inventive concept may not be limited thereto, and a plurality of second semiconductor chip stack structures 602 may disposed between the first and third semiconductor chip stack structures 601 and 603. That is, the third and second semiconductor chips 300 and 200 may be alternately and repeatedly stacked in the vertical direction between the first and third semiconductor chip stack structures 601 and 603.

As described above, the first and second semiconductor chips 100 and 200 may be bonded with each other by a TCB process to form the first semiconductor chip stack structure 601, the third and the second semiconductor chips 300 may be bonded with each other by a TCB process to form the second semiconductor chip stack structure 602, and the third and fourth semiconductor chips 300 and 400 may be bonded with each other by a TCB process to form the third semiconductor chip stack structure 603.

The first and second semiconductor chip stack structures 601 and 602, and the second and third semiconductor chip stack structures 602 and 603 may be bonded with each other by a mass reflow process, and spaces therebetween may be filled with the mold member 500.

If a plurality of semiconductor chips 200 and the fourth semiconductor chip 400 are mounted on the first semiconductor chip 100 without forming the third semiconductor chip 300, and the second and fourth semiconductor chips 200 and 400 are bonded to the first semiconductor chip 100, each of the second semiconductor chips 200 having a thin thickness may be warped.

That is, in order to realize a high capacity memory in a given volume, the number of the second semiconductor chips 200 included in the semiconductor package has to increase, and thus each of the second semiconductor chips 200 may have a reduced thickness in the vertical direction, so that warpage may occur when the second semiconductor chips 200 are bonded with each other by a mass reflow process.

However, in example embodiments, each of the second semiconductor chips 200 may be bonded with the third semiconductor chip 300 by a TCB process to form the second semiconductor chip stack structure 602, and as the second semiconductor chip stack structure 602 may have a vertical thickness greater than that of the second semiconductor chip 200, when the second semiconductor chip stack structure 602 is bonded with the first semiconductor chip stack structure 601 or the third semiconductor chip stack structure 603, the warpage may be reduced or prevented.

Accordingly, the third conductive connection members 390 between neighboring ones of the first to third semiconductor chip stack structures 601, 602 and 603, respectively, may be well bonded with the fourth conductive pad 270 of the second semiconductor chip 200 and the fifth conductive pad 350 of the third semiconductor chip 300, and the electrical connections between the first to third semiconductor chip stack structures 601, 602 and 603 may be enhanced.

The first and second semiconductor chip stack structures 601 and 602, and the second and third semiconductor chip stack structures 602 and 603 may be bonded with each other not by a TCB process but by a mass reflow process, and thus, the bonding time may be reduced when compared to bonding by the TCB process.

That is, the second semiconductor chips 200 may be divided into a plurality of groups (in some embodiments, the third semiconductor chip 300 may have substantially the same function as the second semiconductor chip 200), and ones of the second semiconductor chips 200 in each of the groups may be bonded with each other by a TCB process so as to prevent the warpage of the second semiconductor chips 200, while the groups of the second semiconductor chips 200 may be bonded with each other by a mass reflow process so as to reduce the bonding time.

As a result, in the method of manufacturing the semiconductor device in accordance with example embodiments, the warpage of each of the second semiconductor chips 200 may be prevented, and the bonding time may be reduced.

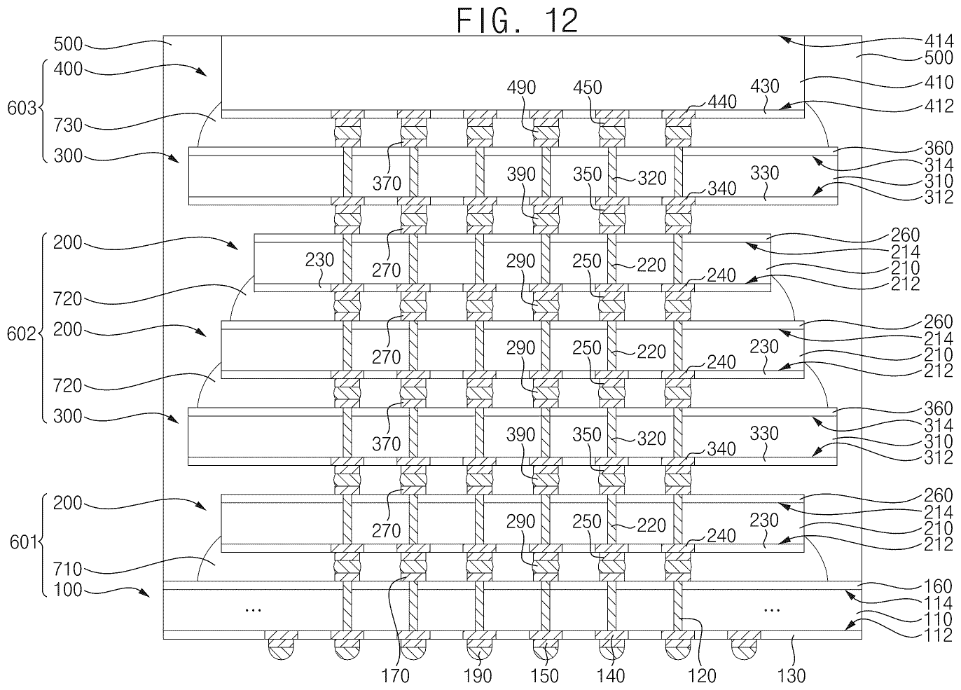

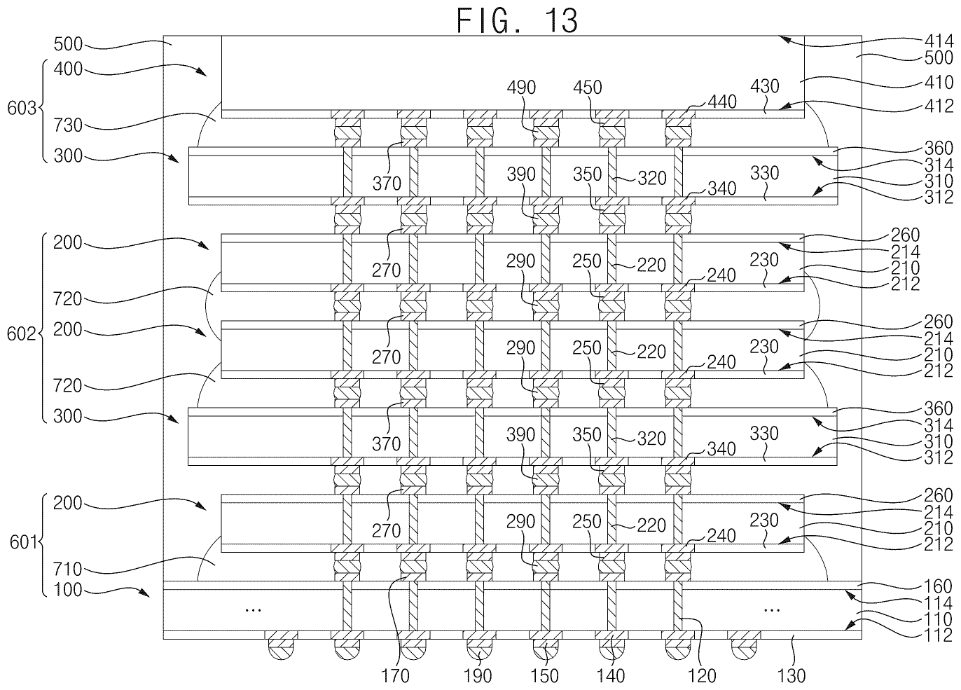

FIGS. 12 and 13 are cross-sectional views illustrating semiconductor packages in accordance with example embodiments. These semiconductor packages may be substantially the same as or similar to that of FIG. 1 except for the second semiconductor chip stack structure, and thus repeated explanations may be omitted herein in the interest of brevity.

Referring to FIG. 12, the second semiconductor chip stack structure 602 may include the third semiconductor chip 300 and two second semiconductor chips 200 stacked in the vertical direction on the third semiconductor chip 300.

In example embodiments, the third and second semiconductor chips 300 and 200 included in the second semiconductor chip stack structure 602 may be bonded with each other by a TCB process, and the second semiconductor chips 200 may be bonded with each other by a TCB process. Thus, the second conductive connection member 290 and the second adhesion layer 720 may be interposed between the third and second semiconductor chips 300 and 200 and between the second semiconductor chips 200.

In example embodiments, a planar area of a first one of the second semiconductor chips 200 at a relatively upper level in the second semiconductor chip stack structure 602 (e.g., the uppermost one of the second semiconductor chips 200 in the second semiconductor chip stack structure 602) may be smaller than a planar area of a second one of the second semiconductor chips 200 at a relatively lower level in the second semiconductor chip stack structure 602 (e.g., the lowermost one of the second semiconductor chips 200 in the second semiconductor chip stack structure 602), and an edge portion of the second one of the second semiconductor chips 200 may not overlap the first one of the second semiconductor chips 200 in the vertical direction.

In example embodiments, a portion of the second adhesion layer 720 between the second semiconductor chips 200 may protrude in the horizontal direction aside or away from a sidewall or side surface of the first one of the second semiconductor chips 200, and may contact a lower sidewall or lower surface of the first one of the second semiconductor chips 200, and the portion of the second adhesion layer 720 may be disposed on the edge portion of the second one of the second semiconductor chips 200 not overlapping the first one of the second semiconductor chips 200 in the vertical direction.

Referring to FIG. 13, as the semiconductor package shown in FIG. 12, the second semiconductor chip stack structure 602 may include the third semiconductor chip 300 and two second semiconductor chips 200 stacked in the vertical direction on the third semiconductor chip 300, and the third and second semiconductor chips 300 and 200 and the second semiconductor chips 200 may be bonded with each other by a TCB process.

However, unlike the semiconductor package shown in FIG. 12, the planar area of the first one of the second semiconductor chips 200 at the relatively upper level in the second semiconductor chip stack structure 602 (e.g., the uppermost one of the second semiconductor chips 200 in the second semiconductor chip stack structure 602) may be substantially the same as the planar area of the second one of the second semiconductor chips 200 at the relatively lower level in the second semiconductor chip stack structure 602 (e.g., the lowermost one of the second semiconductor chips 200 in the second semiconductor chip stack structure 602), and an entire portion of the second one of the second semiconductor chips 200 may overlap the first one of the second semiconductor chips 200 in the vertical direction.

In example embodiments, a portion of the second adhesion layer 720 between the second semiconductor chips 200 may protrude in the horizontal direction aside or away from a sidewall or side surface of each of the second semiconductor chips 200, and may contact a sidewall or side surface of each of the second semiconductor chips 200, particularly, a lower sidewall or a lower portion of the side surface of the first one of the second semiconductor chips 200 and an upper sidewall or an upper portion of the side surface of the second one of the second semiconductor chips 200.

FIGS. 12 and 13 show that the second semiconductor chip stack structure 602 includes two second semiconductor chips 200 stacked on the third semiconductor chip 300 in the vertical direction, however, the inventive concept may not be limited thereto, and the second semiconductor chip stack structure 602 may include more than two second semiconductor chips 200 stacked on the third semiconductor chip 300 in the vertical direction.

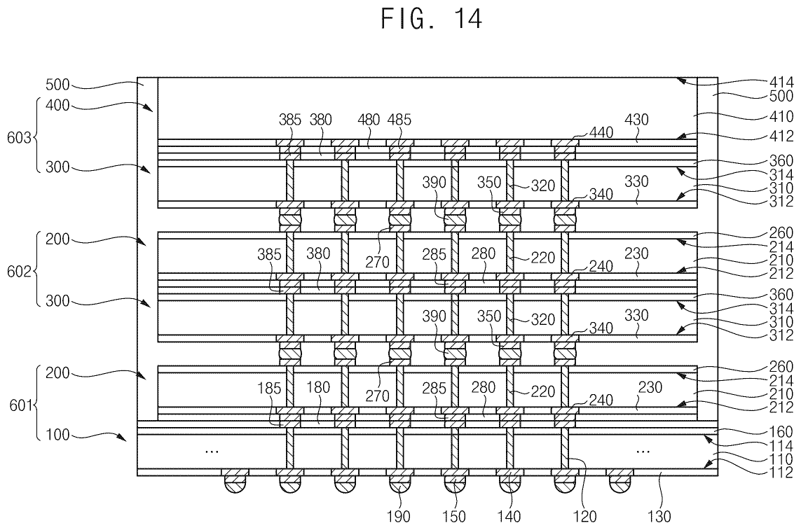

FIG. 14 is a cross-sectional view illustrating a semiconductor package in accordance with example embodiments. This semiconductor package may be substantially the same as or similar to that of FIG. 1 except for some elements, and thus repeated explanations may be omitted herein in the interest of brevity.

Referring to FIG. 14, the first to third semiconductor chip stack structures 601, 602 and 603 may include the first to fourth semiconductor chips 100, 200, 300 and 400 bonded with each other not by a TCB process but by a hybrid copper bonding (HCB) process.

Particularly, in the first semiconductor chip stack structure 601, the first semiconductor chip 100 and the second semiconductor chip 200 may be bonded with each other by an HCB process. Thus, a first bonding layer 180 containing a first bonding pattern 185 therein may be formed on the first protective pattern structure 160 and the first through electrode 120 of the first semiconductor chip 100, a second bonding layer 280 containing a second bonding pattern 285 therein may be formed beneath the fourth insulating interlayer 230 of the second semiconductor chip 200, and the first and second bonding layers 180 and 280 may be bonded with each other to form a first bonding layer structure and the first and second bonding patterns 185 and 285 may be bonded with each other to form a first bonding pattern structure.

Additionally, in the second semiconductor chip stack structure 602, the third semiconductor chip 300 and the second semiconductor chip 200 may be bonded with each other by an HCB process. Thus, a third bonding layer 380 containing a third bonding pattern 385 therein may be formed on the third protective pattern structure 360 and the third through electrode 320 of the third semiconductor chip 300, the second bonding layer 280 containing the second bonding pattern 285 therein may be formed beneath the fourth insulating interlayer 230 of the second semiconductor chip 200, and the third and second bonding layers 380 and 280 may be bonded with each other to form a second bonding layer structure and the third and second bonding patterns 385 and 285 may be bonded with each other to form a second bonding pattern structure.

Furthermore, in the third semiconductor chip stack structure 603, the third semiconductor chip 300 and the fourth semiconductor chip 400 may be bonded with each other by an HCB process. Thus, the third bonding layer 380 containing the third bonding pattern 385 therein may be formed on the third protective pattern structure 360 and the third through electrode 320 of the third semiconductor chip 300, a fourth bonding layer 480 containing a fourth bonding pattern 485 therein may be formed beneath the eighth insulating interlayer 430 of the fourth semiconductor chip 400, and the third and fourth bonding layers 380 and 480 may be bonded with each other to form a third bonding layer structure and the third and fourth bonding patterns 385 and 485 may be bonded with each other to form a third bonding pattern structure.

Alternatively, a first one of the first to third semiconductor chip stack structures 601, 602 and 603 may include semiconductor chips bonded with each other by a TCB process and a second one of the first to third semiconductor chip stack structures 601, 602 and 603 may include semiconductor chips bonded with each other by an HCB process.

In example embodiments, each of the first to fourth bonding layers 180, 280, 380 and 480 may include, e.g., silicon carbonitride or silicon oxide, and each of the first to fourth bonding patterns 185, 285, 385 and 485 may include a metal, e.g., copper.

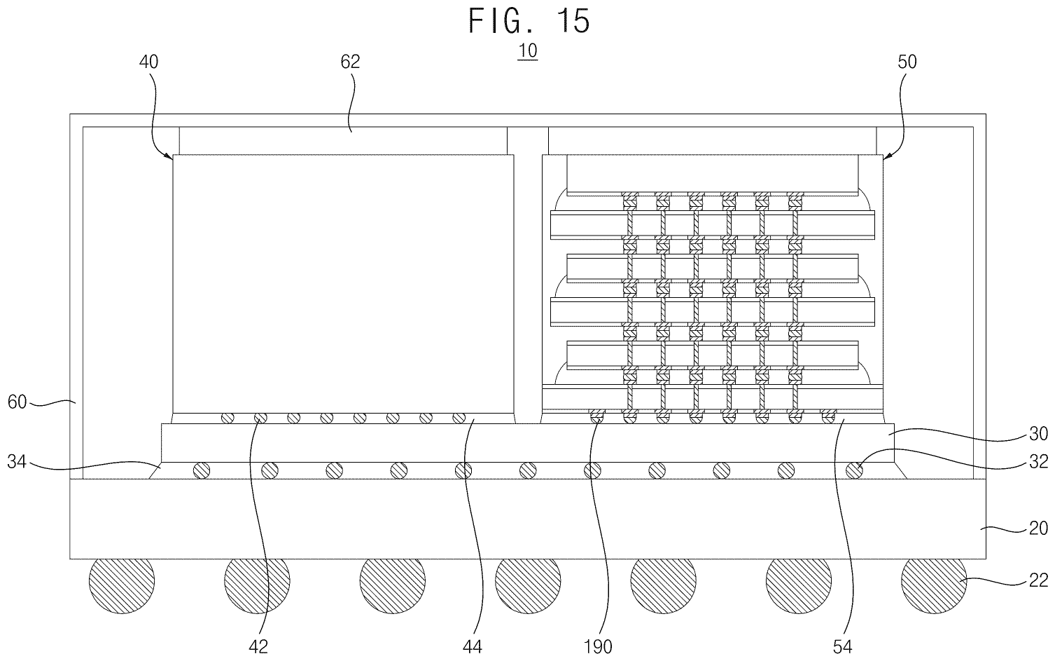

FIG. 15 is a cross-sectional view illustrating an electronic device in accordance with example embodiments.

This electronic device may include the semiconductor package shown in FIG. 1 as a second semiconductor device 50, however, the inventive concept may not be limited thereto, and may include the semiconductor packages shown in FIGS. 12 to 14, as the second semiconductor device 50.

Referring to FIG. 15, an electronic device 10 may include a package substrate 20, an interposer 30, a first semiconductor device 40 and the second semiconductor device 50. The electronic device 10 may further include first, second and third underfill members 34, 44 and 54, a heat slug 60 and a heat dissipation member 62.

In example embodiments, the electronic device 10 may be a memory module having a 2.5D package structure, and thus may include the interposer 30 for electrically connecting the first and second semiconductor devices 40 and 50 to each other.

In example embodiments, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may include a semiconductor package, e.g., an HBM package.

In example embodiments, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a sixth conductive connection member 32. In example embodiments, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the sixth conductive connection member 32. The sixth conductive connection member 32 may include, e.g., a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a TCB process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a seventh conductive connection member 42. For example, the seventh conductive connection member 42 may include, e.g., a micro-bump.

Alternatively, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by a TCB process. In this case, conductive pads of the second semiconductor device 50 may be electrically connected to conductive pads of the interposer 30 by the first conductive connection member 190.

Although a single first semiconductor device 40 and a single second semiconductor device 50 are shown disposed on the interposer 30, the inventive concept may not be limited thereto, and a plurality of first semiconductor devices 40 and/or a plurality of second conductive devices 50 may be disposed on the interposer 30.

In example embodiments, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44 and 54 may include an adhesive containing an epoxy material.

In example embodiments, the heat slug 60 may cover the package substrate 20 to thermally contact the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be formed at a lower portion of the package substrate 20, and a fifth conductive connection member 22 may be disposed beneath the conductive pad. In example embodiments, a plurality of fifth conductive connection members 22 may be spaced apart from each other in the horizontal direction. The fifth conductive connection member 22 may be, e.g., a solder ball. The electronic device 10 may be mounted on a module board via the sixth fifth connection members 22 to form a memory module.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the example embodiments as defined in the claims.

What is claimed is:

1. A semiconductor package comprising:
a first semiconductor chip stack structure including:
a first semiconductor chip having a first planar area;
a second semiconductor chip on the first semiconductor chip, the second semiconductor chip having a second planar area smaller than the first planar area; and
a first adhesion layer between the first and second semiconductor chips, the first adhesion layer bonding the first and second semiconductor chips to each other;
a second semiconductor chip stack structure on and bonded with the first semiconductor chip stack structure, the second semiconductor chip stack structure including:
a third semiconductor chip having a third planar area smaller than the first planar area and greater than the second planar area;
a fourth semiconductor chip on the third semiconductor chip, the fourth semiconductor chip having the second planar area; and
a second adhesion layer between the third and fourth semiconductor chips, the second adhesion layer bonding the third and fourth semiconductor chips to each other;
a third semiconductor chip stack structure on the second semiconductor chip stack structure, the third semiconductor chip stack structure including:
a fifth semiconductor chip having the third planar area;
a sixth semiconductor chip on the fifth semiconductor chip, the sixth semiconductor chip having the second planar area; and
a third adhesion layer between the fifth and sixth semiconductor chips, the third adhesion layer bonding the fifth and sixth semiconductor chips to each other; and
a molding member on the first semiconductor chip, the molding member covering sidewalls of the first adhesion layer, the second semiconductor chip, and the second and third semiconductor chip stack structures.

2. The semiconductor package according to claim 1, wherein the second adhesion layer contacts a portion of the third semiconductor chip not overlapping the fourth semiconductor chip in a vertical direction.

3. The semiconductor package according to claim 1, wherein:
the first and second semiconductor chips are electrically connected to each other by a first conductive bump in the first adhesion layer,
the third and fourth semiconductor chips are electrically connected to each other by a second conductive bump in the second adhesion layer, and
the fifth and sixth semiconductor chips are electrically connected to each other by a third conductive bump in the third adhesion layer.

4. The semiconductor package according to claim 1, wherein the first and second semiconductor chip stack structures are electrically connected to each other by a first conductive bump, and the second and third semiconductor chip stack structures are electrically connected to each other by a second conductive bump.

5. The semiconductor package according to claim 4, wherein the molding member covers sidewalls of the first and second conductive bumps.

6. The semiconductor package according to claim 1, wherein the second semiconductor chip stack structure includes:
a seventh semiconductor chip on the fourth semiconductor chip, the seventh semiconductor chip having a fourth planar area smaller than the second planar area; and
a fourth adhesion layer between the fourth and seventh semiconductor chips, the fourth adhesion layer bonding the fourth and seventh semiconductor chips to each other.

7. The semiconductor package according to claim 6, wherein the fourth adhesion layer contacts a portion of the fourth semiconductor chip not overlapping the seventh semiconductor chip in a vertical direction.

8. The semiconductor package according to claim 1, wherein the second semiconductor chip stack structure includes:
a seventh semiconductor chip on the fourth semiconductor chip, the seventh semiconductor chip having the second planar area; and
a fourth adhesion layer between the fourth and seventh semiconductor chips, the fourth adhesion layer bonding the fourth and seventh semiconductor chips to each other.

9. The semiconductor package according to claim 1, further comprising a fourth semiconductor chip stack structure between the second semiconductor chip stack structure and the third semiconductor chip stack structure, the fourth semiconductor chip stack structure including:
a seventh semiconductor chip having the third planar area;
an eighth semiconductor chip on the seventh semiconductor chip, the eighth semiconductor chip having the second planar area; and
a fourth adhesion layer between the seventh and eighth semiconductor chips, the fourth adhesion layer bonding the seventh and eighth semiconductor chips to each other.

10. The semiconductor package according to claim 1, wherein the first semiconductor chip includes a logic device, and each of the second to sixth semiconductor chips includes a memory device.

11. The semiconductor package according to claim 1, wherein the second to fifth semiconductor chips include memory devices having the same function.

12. A semiconductor package comprising:
a first semiconductor chip stack structure including:
a first semiconductor chip;
a second semiconductor chip on the first semiconductor chip; and
a first bonding layer structure between the first and second semiconductor chips, the first bonding layer structure bonding the first and second semiconductor chips to each other, and surrounding a first bonding pattern structure that contacts the first and second semiconductor chips;
a second semiconductor chip stack structure including:
a third semiconductor chip;
a fourth semiconductor chip on the third semiconductor chip; and
a second bonding layer structure between the third and fourth semiconductor chips, the second bonding layer structure bonding the third and fourth semiconductor chips to each other, and surrounding a second bonding pattern structure that contacts the third and fourth semiconductor chips;
a third semiconductor chip stack structure including:
a fifth semiconductor chip;
a sixth semiconductor chip on the fifth semiconductor chip; and
a third bonding layer structure between the fifth and sixth semiconductor chips, the third bonding layer structure bonding the fifth and sixth semiconductor chips to each other, and surrounding a third bonding pattern structure that contacts the fifth and sixth semiconductor chips; and
a molding member on the first semiconductor chip, the molding member surrounding sidewalls of the first bonding layer structure, the second semiconductor chip, and the second and third semiconductor chip stack structures,
wherein:
the first and second semiconductor chip stack structures are bonded to each other with a first conductive bump therebetween,
the second and third semiconductor chip stack structures are bonded to each other with a second conductive bump therebetween, and
the molding member contacts and surrounds side surfaces of the first and second conductive bumps.

13. The semiconductor package according to claim 12, wherein the first semiconductor chip includes a logic device, and each of the second to sixth semiconductor chips includes a memory device.

14. The semiconductor package according to claim 12, wherein the second to fifth semiconductor chips include memory devices having the same function.

15. The semiconductor package according to claim 12, wherein each of the first to third bonding layer structures include silicon carbonitride or silicon oxide, and
wherein each of the first to third bonding pattern structures include copper.

16. A semiconductor package comprising:
a first semiconductor chip stack structure including:
a first semiconductor chip having a first planar area;
a second semiconductor chip on the first semiconductor chip, the second semiconductor chip having a second planar area smaller than the first planar area;
a first conductive connection member between the first and second semiconductor chips, the first conductive connection member electrically connecting the first and second semiconductor chips to each other;
a first adhesion layer between the first and second semiconductor chips, the first adhesion layer bonding the first and second semiconductor chips to each other and covering a sidewall of the first conductive connection member;
a second semiconductor chip stack structure on the first semiconductor chip stack structure, the second semiconductor chip stack structure including:
a third semiconductor chip having a third planar area smaller than the first planar area and greater than the second planar area;
a fourth semiconductor chip on the third semiconductor chip, the fourth semiconductor chip having the second planar area;
a second conductive connection member between the third and fourth semiconductor chips, the second conductive connection member electrically connecting the third and fourth semiconductor chips to each other; and
a second adhesion layer between the third and fourth semiconductor chips, the second adhesion layer bonding the third and fourth semiconductor chips to each other and covering a sidewall of the second conductive connection member;
a third semiconductor chip stack structure on the second semiconductor chip stack structure, the third semiconductor chip stack structure including:
a fifth semiconductor chip having the third planar area;
a sixth semiconductor chip on the fifth semiconductor chip, the sixth semiconductor chip having the second planar area;
a third conductive connection member between the fifth and sixth semiconductor chips, the third conductive connection member electrically connecting the fifth and sixth semiconductor chips to each other; and
a third adhesion layer between the fifth and sixth semiconductor chips, the third adhesion layer bonding the fifth and sixth semiconductor chips to each other and covering a sidewall of the third conductive connection member;
a fourth conductive connection member between the first and second semiconductor chip stack structures, the fourth conductive connection member electrically connecting the first and second semiconductor chip stack structures to each other;
a fifth conductive connection member between the second and third semiconductor chip stack structures, the fifth conductive connection member electrically connecting the second and third semiconductor chip stack structures to each other; and
a molding member on the first semiconductor chip, the molding member covering sidewalls of the first adhesion layer, the second semiconductor chip, the second and third semiconductor chip stack structures, and the fourth and fifth conductive connection members.

17. The semiconductor package according to claim 16, wherein the second adhesion layer contacts a portion of the third semiconductor chip not overlapping the fourth semiconductor chip in a vertical direction.

18. The semiconductor package according to claim 16, wherein the second semiconductor chip stack structure includes:
a seventh semiconductor chip on the fourth semiconductor chip, the seventh semiconductor chip having a fourth planar area smaller than the second planar area;
a sixth conductive connection member between the fourth and seventh semiconductor chips, the sixth conductive connection member electrically connecting the fourth and seventh semiconductor chips to each other; and
a fourth adhesion layer between the fourth and seventh semiconductor chips, the fourth adhesion layer bonding the fourth and seventh semiconductor chips to each other.

19. The semiconductor package according to claim 16, wherein the second semiconductor chip stack structure includes:
a seventh semiconductor chip on the fourth semiconductor chip, the seventh semiconductor chip having the second planar area;
a sixth conductive connection member between the fourth and seventh semiconductor chips, the sixth conductive connection member electrically connecting the fourth and seventh semiconductor chips to each other; and
a fourth adhesion layer between the fourth and seventh semiconductor chips, the fourth adhesion layer bonding the fourth and seventh semiconductor chips to each other.

20. The semiconductor package according to claim 16, wherein the first semiconductor chip includes a logic device, and each of the second to sixth semiconductor chips includes a memory device.
